(19) United States
(12) Patent Application Publication
(10) Pub. No.: US 2011/0048504 A1
(43) Pub. Date: Mar. 3, 2011

(54) PHOTOVOLTAIC ARRAY, FRAMEWORK, AND METHODS OF INSTALLATION AND USE

(75) Inventors: Richard Dale Kinard, Wilmington, DE (US); Michael Robert Mc Quade, Greenville, DE (US)

(73) Assignee: E.I. DU PONT DE NEMOURS AND COMPANY, Wliminton, DE (US)

(21) Appl. No.: 12/809,850

(22) PCT Filed: Dec. 22, 2008
(86) PCT No.: PCT/US08/87893

§ 371 Date: Oct. 6, 2010

Related U.S. Application Data
(60) Provisional application No. 61/015,829, filed on Dec. 21, 2007.
(60) Provisional application No. 61/104,834, filed on Oct. 13, 2008.
(60) Provisional application No. 61/104,838, filed on Oct. 13, 2008.
(60) Provisional application No. 61/104,841, filed on Oct. 13, 2008.

(51) Int. Cl. H01L 31/048; H01L 31/05

(52) U.S. Cl. 136/251; 257/E31.001

(57) ABSTRACT

A photovoltaic array having a framework comprising a plurality of electrically and mechanically interconnected electrically non-conductive framework elements disposed to supportively receive and mutually electrically interconnect a plurality of photovoltaic modules; a plurality of photovoltaic modules supportively disposed upon the plurality of framework elements and electrically interconnected therewith, each photovoltaic module having one or more edges that define a periphery; and, an electrical connection between the photovoltaic array and an external electrical load; and, wherein each the framework element has a pair of generally parallel rails and a pair of generally parallel stiles interconnected therewith, wherein at least one rail and/or stile is an electrically non-conductive hollow member having an interior, the interior defining a fully enclosed guideway; a longitudinally extended electrically conductive member disposed in at least one the guideway; one or more electrical connectors disposed interior to the at least one hollow member; and, wherein a combination of the wires and the connectors electrically interconnect the frame elements and the photovoltaic modules to one another. The method of installation and the method of use are also included herein.

Priority is claimed to U.S. Provisional Application No. 61/015,829 filed on Dec. 21, 2007, to U.S. Provisional Application No. 61/104,834 filed on Oct. 13, 2008, to U.S. Provisional Application No. 61/104,838 filed on Oct. 13, 2008, and to U.S. Provisional Application No. 61/104,841 filed on Oct. 13, 2008, which are all herein incorporated by reference.

### FIELD OF INVENTION

The present invention is directed to a photovoltaic array having an interconnected electrically non-conductive framework, the method for assembling the photovoltaic array, and a method for use thereof. The array does not have to be electrically grounded.

### BACKGROUND

Commercially available solar energy photovoltaic arrays involve a large number of electrically conducting metallic structural components that need to be grounded. Some examples are included in the following,

Erling et al., U.S. Pat. No. 7,012,188, discloses a system for roof-mounting plastic enclosed photovoltaic modules in residential settings.

Mapes et al., U.S. Pat. No. 6,617,507, discloses a system of elongated rails of an extruded resin construction having grooves for holding photovoltaic modules.

Metten et al., U.S. Patent Publication 2007/0157963, discloses a modular system that includes a composite tile made by molding and extrusion processes, a track system for connecting the tiles to a roof, and a wiring system for integrating photovoltaic modules into the track and tile system.

Garvison et al., U.S. Pat. No. 6,465,724, discloses a multipurpose photovoltaic module framing system which combines and integrates the framing system with the photovoltaic electrical system. Some components of the system can be made of plastic. Ground clips can be directly connected to the framing system.

### SUMMARY OF THE INVENTION

In one aspect, the present invention provides a framework comprising a plurality of interconnected electrically non-conductive framework elements disposed to supportingly receive and mutually interconnect a plurality of photovoltaic modules, each the framework element comprising
a pair of generally parallel rails and a pair of generally parallel stiles interconnected therewith, wherein at least one rail and/or stile is an electrically non-conductive hollow member having an interior, the interior defining a fully enclosed guideway;
one or more longitudinally extended electrically conductive member disposed in at least one the guideway;
one or more electrical connector disposed interior to the at least one hollow member;
wherein a combination of the electrically conductive member and the at least one connector is disposed to electrically interconnect the frame element to another frame element or to one or more photovoltaic module upon installation thereof into the frame elements, thereby forming a photovoltaic array.

In another aspect, the present invention provides a photovoltaic array comprising
a framework comprising a plurality of interconnected electrically non-conductive framework elements disposed to supportingly receive and mutually interconnect a plurality of photovoltaic modules;
a plurality of photovoltaic modules supportingly disposed upon the plurality of framework elements and interconnected therewith, each photovoltaic module having one or more edges that define a periphery;
and,
an electrical connection between the photovoltaic array and an external electrical load; and,
wherein each the framework element comprises
   a pair of generally parallel rails and a pair of generally parallel stiles interconnected therewith, wherein at least one rail and/or stile is an electrically non-conductive hollow member having an interior, the interior defining a fully enclosed guideway;
   a longitudinally extended electrically conductive member disposed in at least one the guideway;
   one or more electrical connectors disposed interior to the at least one hollow member; and,
   wherein a combination of the longitudinally extended electrically conductive member and the at least one connector electrically interconnect the frame elements and the photovoltaic modules to one another, and to an electrical output connection disposed to permit electrical connection of the array to an external electrical load

The invention is further directed to a method comprising
supportively disposing a plurality of photovoltaic modules, each having one or more edges that define a periphery, in a supported framework comprising a plurality of interconnected electrically non-conductive framework elements;
forming electrical interconnections between each the photovoltaic module and the framework or another photovoltaic module, thereby forming an array of interconnected photovoltaic modules; and,
providing the framework with an electrical output connection to connect the array to an external electrical load;
wherein each framework element comprises
   a pair of generally parallel rails and a pair of generally parallel stiles interconnected therewith, wherein at least one rail and/or stile is an electrically non-conductive hollow member having an interior, the interior defining a fully enclosed guideway;
   a longitudinally extended electrically conductive member disposed in at least one the guideway;
   one or more electrical connectors disposed interior to the at least one hollow member; and,
   wherein a combination of the longitudinally extended electrically conductive member and the at least one connector electrically interconnect the frame elements and the photovoltaic modules to one another, and to the electrical output connection disposed to permit electrical connection of the array to an external electrical load.

In a further aspect, the present invention provides a method comprising illuminating a photovoltaic array with sunlight thereby generating an electrical current from the photovoltaic array, the photovoltaic array comprising
a framework comprising a plurality of interconnected electrically non-conductive framework elements disposed to supportingly receive and mutually interconnect a plurality of photovoltaic modules;
a plurality of photovoltaic modules supportingly disposed upon the plurality of framework elements and interconnected therewith, each photovoltaic module having one or more edges that define a periphery;
and,
an electrical connection between the photovoltaic array and an external electrical load; and,
wherein each the framework element comprises
   a pair of generally parallel rails and a pair of generally parallel stiles interconnected therewith, wherein at least one rail and/or stile is an electrically non-conductive hollow member having an interior, the interior defining a fully enclosed guideway;
   a longitudinally extended electrically conductive member disposed in at least one the guideway;
   one or more electrical connectors disposed interior to the at least one hollow member; and,
   wherein a combination of the longitudinally extended electrically conductive member and the at least one connector electrically interconnect the frame elements and the photovoltaic modules to one another, and to an electrical output connection disposed to permit electrical connection of the array to an external electrical load
      and,
      providing electrical power to the external electrical load.

### BRIEF DESCRIPTION OF THE DRAWINGS

FIG. 1A illustrates a residential rooftop upon which is disposed a photovoltaic array.

FIG. 1B illustrates the basic components that make up a photovoltaic panel.

FIGS. 1C-1E illustrate embodiments of structurally supported photovoltaic panels.

FIG. 3A illustrates an embodiment of a wiring harness and connections found within a framework design.

FIGS. 3B-3D illustrate embodiments of internally enclosed jumper wires and connectors built into the framework design.

FIG. 4A illustrates an embodiment of a method of installation of a photovoltaic panel onto a framework element, and electrical connection alternatives.

FIG. 4B illustrates an embodiment of mechanical connectors on the framework element.

FIG. 4C illustrates an embodiment wherein standard, generally weather-proof connectors are employed for effecting the electrical connections between the cables leading from the junction box of a photovoltaic panel to the framework element.

FIG. 4D illustrates a recessed connecting element that is built into the structural member of the frame element that is suitable for use when the photovoltaic panel comprises internally disposed connecting elements that align with the connecting element shown in the figure.

FIG. 4E illustrates an embodiment of the method for installing photovoltaic panels into the frame element, and two alternative embodiments for effecting the electrical connection. On the left of the figure can be seen a junction box with cables, and on the right a junction box with bulkhead mounted connectors lined up with connectors on the framework element.

FIGS. 4F and 4G illustrate an embodiment of the method of installing photovoltaic panels into the frame element wherein the electrical connection elements are built into the frame of the photovoltaic panel and corresponding connection elements are built into the framework element.

FIG. 5A illustrates an embodiment of a photovoltaic array wired in series.

FIG. 5B illustrates an embodiment of a photovoltaic array wired in the combination of parallel and series.

FIGS. 5C-5E illustrates wiring harness and links.

### DETAILED DESCRIPTION

The present invention provides a framework having a plurality of interconnected electrically non-conductive framework elements disposed to supportingly receive and mutually interconnect a plurality of photovoltaic modules, each the framework element comprising a pair of generally parallel rails and a pair of generally parallel stiles interconnected therewith, wherein at least one rail and/or stile is an electrically non-conductive hollow member having an interior, the interior defining a fully enclosed guideway; one or more longitudinally extended electrically conductive member disposed in at least one the guideway; one or more electrical connector disposed interior to the at least one hollow member; and, wherein a combination of the electrically conductive member and the at least one connector is disposed to electrically interconnect the frame element to another frame element or to one or more photovoltaic module upon installation thereof into the frame elements, thereby forming a photovoltaic array.

In another aspect, the present invention provides a photovoltaic array having a framework comprising a plurality of interconnected electrically non-conductive framework elements disposed to supportingly receive and mutually interconnect a plurality of photovoltaic modules; a plurality of photovoltaic modules supportingly disposed upon the plurality of framework elements and interconnected therewith, each photovoltaic module having one or more edges that define a periphery; and, an electrical connection between the photovoltaic array and an external electrical load; and, wherein each the framework element having a pair of generally parallel rails and a pair of generally parallel stiles interconnected therewith, wherein at least one rail and/or stile is an electrically non-conductive hollow member having an interior, the interior defining a fully enclosed guideway; a longitudinally extended electrically conductive member disposed in at least one the guideway; one or more electrical connectors disposed interior to the at least one hollow member; and, wherein a combination of the longitudinally extended electrically conductive member and the at least one connector electrically interconnect the frame elements and the photovoltaic modules to one another, and to the external electrical load.

The invention is further directed to a method having supportively disposing a plurality of photovoltaic modules, each having one or more edges that define a periphery, in a supported framework comprising a plurality of interconnected electrically non-conductive framework elements; forming electrical interconnections between each the photovoltaic module and the framework or another photovoltaic module, thereby forming an array of interconnected photovoltaic modules; and, providing the framework with an electrical output connection disposed to permit electrical connection of the array to an external electrical load; wherein each the framework element comprises a pair of generally parallel rails and a pair of generally parallel stiles interconnected therewith, wherein at least one rail and/or stile is an electrically non-conductive hollow member having an interior, the interior defining a fully enclosed guideway; a longitudinally extended electrically conductive member disposed in at least one the guideway; one or more electrical connectors disposed interior to the at least one hollow member; and, wherein a combination of the longitudinally extended electrically conductive member and the at least one connector electrically interconnect the frame elements and the photovoltaic modules to one another, and to the electrical output connection disposed to permit electrical connection of the array to an external electrical load.

In a further aspect, the present invention provides a method for illuminating a photovoltaic array with sunlight thereby generating an electrical current from the photovoltaic array, the photovoltaic array having a framework comprising a plurality of interconnected electrically non-conductive framework elements disposed to supportingly receive and mutually interconnect a plurality of photovoltaic modules;

a plurality of photovoltaic modules supportingly disposed upon the plurality of framework elements and interconnected therewith, each photovoltaic module having one or more edges that define a periphery; and, an electrical connection between the photovoltaic array and an external electrical load; and, wherein each the framework element comprises a pair of generally parallel rails and a pair of generally parallel stiles interconnected therewith, wherein at least one rail and/or stile is an electrically non-conductive hollow member having an interior, the interior defining a fully enclosed guideway; a longitudinally extended electrically conductive member disposed in at least one the guideway; one or more electrical connectors disposed interior to the at least one hollow member; and, wherein a combination of the longitudinally extended electrically conductive member and the at least one connector electrically interconnect the frame elements and the photovoltaic modules to one another, and to an electrical output connection disposed to permit electrical connection of the array to an external electrical load and, providing electrical power to the external electrical load.

As used herein the term “photovoltaic module” refers to a prefabricated array of photovoltaic cells, the associated wiring and connections, and the associated supporting and enclosing structures thereof in the form of a unitary structure—typically a flat, rigid panel—suitable for direct installation in and interconnection with the framework, and thereby with other photovoltaic modules to form a photovoltaic array. Any photovoltaic cell known in the art is suitable for use in the present invention. The term “wiring” in the context of this invention encompasses all forms of interconnecting conductors whether printed conductive pathways, buss bars, single or multi-strand wires, and any other configurations of conductors that are used to conduct electricity from one point to another.

A pair of rails and a pair of stiles that are “generally parallel” shall be understood to mean that the rails and stiles combine to define a quadrilateral of which opposite sides do not intersect with one another. In most embodiments, the rails and stiles will be interconnected to form a rectangle disposed to supportingly receive a rectangular photovoltaic module. In another embodiment the rails and stiles will be interconnected to form a square. In addition, should the photovoltaic module depart from rectangular shape—for example, be fabricated in a trapezoidal shape—the rails and stiles may be disposed to form a quadrilateral wherein opposite sides do not intersect but also are not truly parallel. For descriptive purposes herein the term rail will denote the longer of the rail or stile used during assembly of the array, but the terms may be interchanged.

The term “longitudinally extended electrically conductive member” refers to a metallic wire having conductive thread-like elements, a metallic wire having a rigid rod element, a metallic buss-bar, a printed conductive pathway, or any other extended electrically conductive member that can be disposed within the guideway defined by the interior of the hollow member in the frame element, and provides electrical connection between one point of the hollow interior space and another point therein, as illustrated infra.

In one embodiment, the longitudinally extended electrically conductive member is a metallic wire. In another embodiment the longitudinally extended electrically conductive member is a metallic buss bar.

Further the term “electrical connector” refers to a localized device disposed to effect an electrical connection between the longitudinally extended electrically conductive member and some other electrical device or member, including a corresponding longitudinally extended electrically conductive member disposed within the interior of a different hollow member disposed within the framework.

In one embodiment, the electrical connector is a terminal post. In another embodiment, the electrical connector is a male or female receptacle disposed to interconnect with its respective female or male connector on a different corresponding frame element or photovoltaic module. Combinations of both types, as well as other types not specifically recited here, can be employed within the framework.

In one embodiment, all the rails and stiles are electrically non-conductive hollow members. The rails and stiles may be fabricated from any desired electrically non-conductive materials, including but not limited to ceramics, wood, silicate glasses, and plastic. In one embodiment the rails and stiles are fabricated from plastic.

The term “plastic” encompasses thermoplastic or thermoset organic polymers. All organic polymers suitable for use herein are rigid solids up to 90° C. or above. The term “plastic” shall be understood to encompass unreinforced polymers, particle-filled polymers, short fiber reinforced polymers, long-fiber reinforced polymers, and continuous-fiber reinforced polymers (composite materials). Any electrically non-conductive reinforcing fiber is suitable for use in forming the fiber reinforced polymers suitable for use herein. Suitable fibers include but are not limited to glass, polyaramid, and ceramic.

The term “short fiber reinforced polymer” is a term found in the art referring to a blend of a polymer and a reinforcing fiber characterized by a length of less than about 5 mm, wherein the fiber is dispersed with a continuous matrix of the polymer. The term “long fiber reinforced polymer” is a term of art referring to a blend of a polymer and a reinforcing fiber characterized by a length of about >5 mm-50 mm, wherein the fiber is dispersed with a continuous matrix of the polymer. Continuous fiber reinforced polymers are also known as composite materials. Continuous fiber reinforced polymers generally involve fibers that are comparable in length to the article into which they have been incorporated.

Short and long fiber reinforced polymers may be prepared by extrusion blending, and fabricated by injection molding. Continuous fiber reinforced polymers must be prepared by yarn coating, polymer infusion into yarn bundles and the like. Fabrication may involve vacuum molding, pultrusion and such other methods that have been developed in the art for shaping of composite materials.

Suitable reinforcing fibers include glass fibers, polyaramid fibers, ceramic fibers, and other non-electrically conductive fibers that retain their distinctive fiber properties during processing and fabrication. Fiber reinforced polymers are extremely well-known in the art. Detailed descriptions of compositions, preparation, fabrication, and properties may be found in Garbassi et al. J. Poly. Sci. and Tech., DOI 10.1002/0471440264.pst406, and Goldsworthy et al., J. Poly. Sci. and Tech., DOI 10.1002/0471440264.pst074.

Any of the plastic compositions suitable for use herein may further comprise such additives as are commonly employed in the art of Engineering Polymers, including inorganic fillers, ultra-violet absorbers, plasticizers, anti oxidants, flame retardants, pigmentation and so forth.

Suitable plastics need to exhibit dimensional stability and good retention of mechanical properties when subject to continuous desert temperatures as high as 90-120° C., on surfaces exposed to the sun. Many plastics soften at temperatures below that temperature. Softening is unacceptable both from the standpoint of maintaining coplanarity of the photovoltaic modules and the solar cells of which they are composed, and of flexural, shear, and torsional resistance. Suitable plastics include but are not limited to polyamides, such as nylons, polyesters such as polyethylene terephthalate, polycarbonate, poly ether ketones, including PEK, PEEK, PEKK and the like; polyamideimides, epoxies, and polyimides.

Particular choice of a plastic resin from which to fabricate the framework will depend upon the specific environment in which it will be used, as well as cost. In a bone dry climate such as a desert, nylon polyamide may offer a desirable combination of properties. In a temperate climate, periods of rain and high humidity, will render nylon subject to dimensional instability and hydrolysis. For many purposes long-fiber reinforced polyethylene terephthalate resin is highly satisfactory and cost effective. In one embodiment, Rynite® PET polyester resin, available from the DuPont Company, is employed to fabricate the rails and stiles.

The term “photovoltaic array” refers to an arrangement of one or more photovoltaic modules, defined supra, positioned to convert sunlight (or other illumination) to electrical power. In a present typical photovoltaic array, a plurality of photovoltaic modules is arranged in coplanar array. In a typical commercial installation, a single photovoltaic module receiving full solar illumination outputs 4-5 amperes of current at 24 volts, and a photovoltaic array can output 30 amperes at about 500 to 1000 volts.

Safely handling the electrical power levels and voltage levels of a solar array in outdoor commercial and residential settings requires the grounding of all exposed metal parts; and the protection of electrical connections from corrosion. In the present invention, such connections are partially contained or completely contained within the interior defined by the non-electrically conductive hollow members of the framework element, or are isolated in their own non-conductive housing. No exposure of connectors to corrosive conditions occurs.

The photovoltaic array is characterized in that all of its internal electrical components: including photovoltaic cells, by-pass diodes, electrical conductors and interconnections are encased in and supported by non-conductive frame elements, non-conductive frame segments on the module, or other non-conductive housing. The photovoltaic array allows the output voltage to be electrically referenced to any arbitrary voltage without compromising safety or system integrity. No electrical grounding is required. In addition to the benefits in installation cost and safety associated with the photovoltaic array, there is also a benefit in increased electrical design flexibility over present-day photovoltaic arrays because the system may be installed under conditions where the reference voltage is well above ground potential—something not possible with present-day systems. However, setting the reference potential to ground is not precluded.

A photovoltaic module suitable for use in the photovoltaic array comprises a structural component, a plurality of electrically interconnected photovoltaic cells typically arranged in a parallel coplanar array with an optically clear protective cover, and a protective backing; the photovoltaic cells being sandwiched and sealed between the cover layer and the backing layer. In one embodiment the structural component is a peripheral frame. In an alternative embodiment the structural component is an underlying supporting structure.

In one embodiment, the photovoltaic module further comprises an electrical junction box to which the output wires of the photocells are connected, and from which high voltage cables from the junction box are connected to weather resistant connectors bulkhead mounted on one or more the hollow members, with electrical connections between photovoltaic modules effected by electrical conductors internal to at least a portion of the hollow members.

In a further embodiment, the photovoltaic module has high voltage connecting cables with weather-resistant plugs. In an alternative embodiment, the photovoltaic module is provided with integrated electrical connections within the structure of the module, as described below.

In another embodiment, each rail and stile is fabricated from plastic, each photovoltaic module further comprises a frame segment member enclosing at least a portion of the periphery, the frame segment member housing electrical power output connections; and, wherein all of the electrical conductors and connections that interconnect the photovoltaic modules one to another are internal to at least a portion of the hollow members and the frame segment members.

Photovoltaic modules in present commercial use are coplanar arrays of photovoltaic cells that make up a flat panel. Similarly, photovoltaic arrays in present commercial use are typically in the form of flat coplanar arrays of flat panel photovoltaic modules. However, the present invention is operable in embodiments wherein the photocells in a module, or the modules themselves describe a curved surface rather than a plane.

Any photovoltaic cell that converts sunlight into electrical power is suitable. A typical photovoltaic cell in widespread commercial use comprises layers of doped and undoped silicon, sandwiched between two layers of metal conductors. There are many types of photovoltaic cells in the art, single layer, double layer, triple layer, etc., any of which could be used with this invention, if formed together and electrically interconnected to form a power producing photovoltaic module. Photovoltaic cells are connected in series and/or parallel to obtain the required values of current and voltage for electric power generation in the photovoltaic array.

Several semiconductor compositions have been developed for use as photovoltaic cells in solar modules. Both amorphous and crystalline silicon and crystalline gallium arsenide are typical choices of materials for solar cells. Using means well-known in the art, dopants are introduced into the pure compounds, and metallic conductors are deposited onto each surface: a thin grid on the sun-facing side and usually a flat sheet on the other. Typically, solar cells are made from silicon boules, polycrystalline structures that have the atomic structure of a single crystal. The pure silicon is then doped with phosphorous and boron to produce an excess of electrons in one region and a deficiency of electrons in another region to make a semiconductor capable of conducting electricity. Photovoltaic modules suitable for the practice of the present invention are available commercially from a number of manufacturers, including Evergreen Solar, Inc, Marlboro, Mass.; Solarworld California, Camarillo, Calif., and Mitsubishi Electric Co., New York, N.Y.

Any electrically non-conductive, engineered, structural material including ceramics, wood, and polymers, could be used to form the structural members of the photovoltaic modules and the framework elements. If the material is classified as a non-conductor according to appropriate regional Standards Organizations, such as UL (Underwriters Laboratories), CUL, or TUV, it is appropriate for use in this invention. To be UL certified, materials must meet UL 1703 (Standard for Safety for Flat-Plate Photovoltaic Modules and Modules); UL 498 (Attachment Plugs and Receptacles); and/or UL 1977 (Component Connectors Used for Data, Signal and Power Equipment Applications), as appropriate. Additional information on UL certification can be found at http://www.ul.com/dge/photovoltaics/ and http://www.ul.com/dge/photovoltaics/tests.html

In one embodiment, the photovoltaic module is provided with plastic structural members. In another embodiment, the photovoltaic module has metallic structural members, necessitating that the metallic members that would otherwise be exposed be subject to encapsulation in plastic. Any means for encapsulating in plastic is satisfactory, for example, coatings, extrusions, laminations, bonding, cladding, with the proviso that the encapsulation be weather-resistant.

In one embodiment mechanical connections between framework elements are made of plastic, and are of the snap-together variety. Mechanical connections may be reversible to make replacement of damaged parts easy. Suitable mechanical connections include, but are not limited to: snap-together, spring-loaded, quarter-turn, bayonette, interlocking, and quick connect—disconnect assemblies such as those used in the discrete-part manufacturing industry.

Electrical connections between framework elements may conveniently be effected using conventional high voltage connectors wherein the male connector is located on one component, disposed to mate with the female component disposed on the component to which it is to be connected. Suitable connectors are preferably approved for photovoltaic applications by organizations such as UL and TUV.

In one embodiment, each photovoltaic module is disposed in and connected electrically and mechanically to a framework element made up of rails and stiles. The photovoltaic module is provided with both mechanical and electrical connectors compatible with complementary connectors provided in the framework element to which it is connected. Suitable mechanical connections provided in the photovoltaic module include but are not limited to a frame that snaps into a receiving track on the framework element, and pass-through holes in a frame on the photovoltaic module for mounting to the framework element. In the case where pass-through holes are employed, the mounting screws and mating fasteners, such as threaded standoffs, rivets, inserts or nuts, are either insulated or isolated from the framework elements made of plastic, coated with an insulating surface, capped with an insulating cover or combinations. Electrical connectors should be certified for outdoor use in wet locations with exposure to sunlight (i.e., UV exposure resistance). Power connectors for use with photovoltaic modules and framework should be designed robustly enough to withstand use as a DC circuit interrupt device, under overload conditions, as outlined in UL 498 and UL 1977.

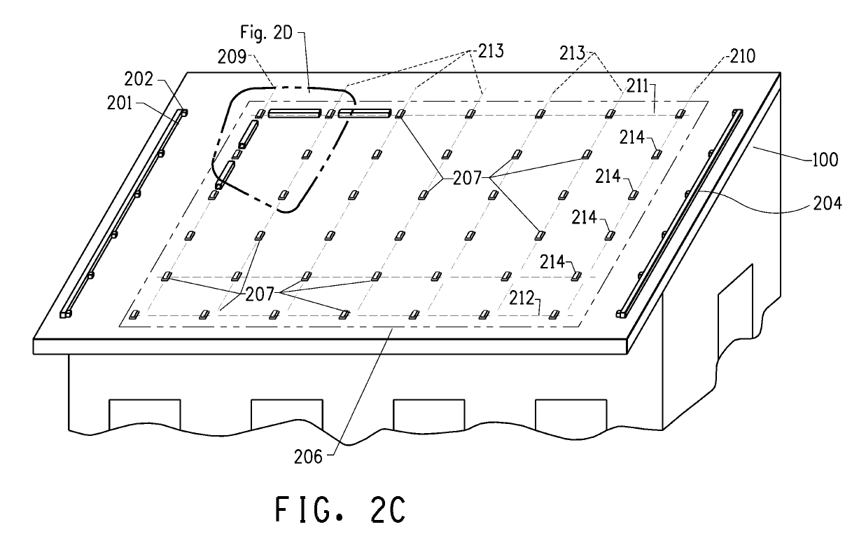

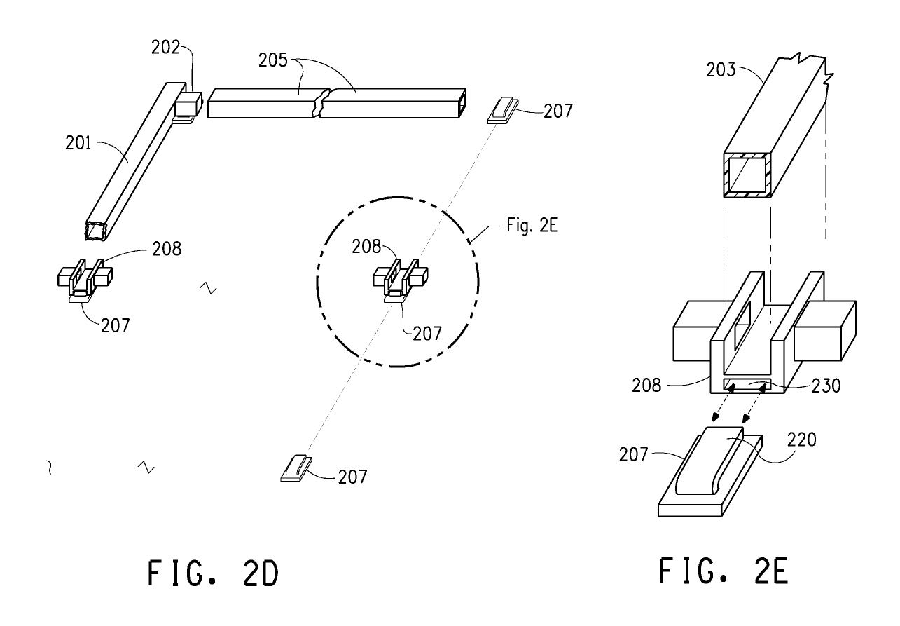

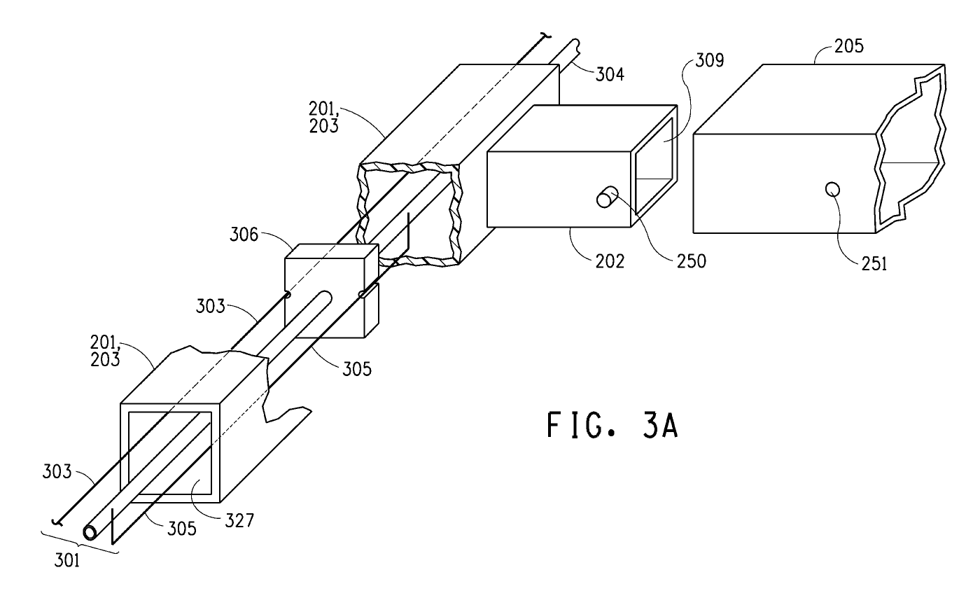

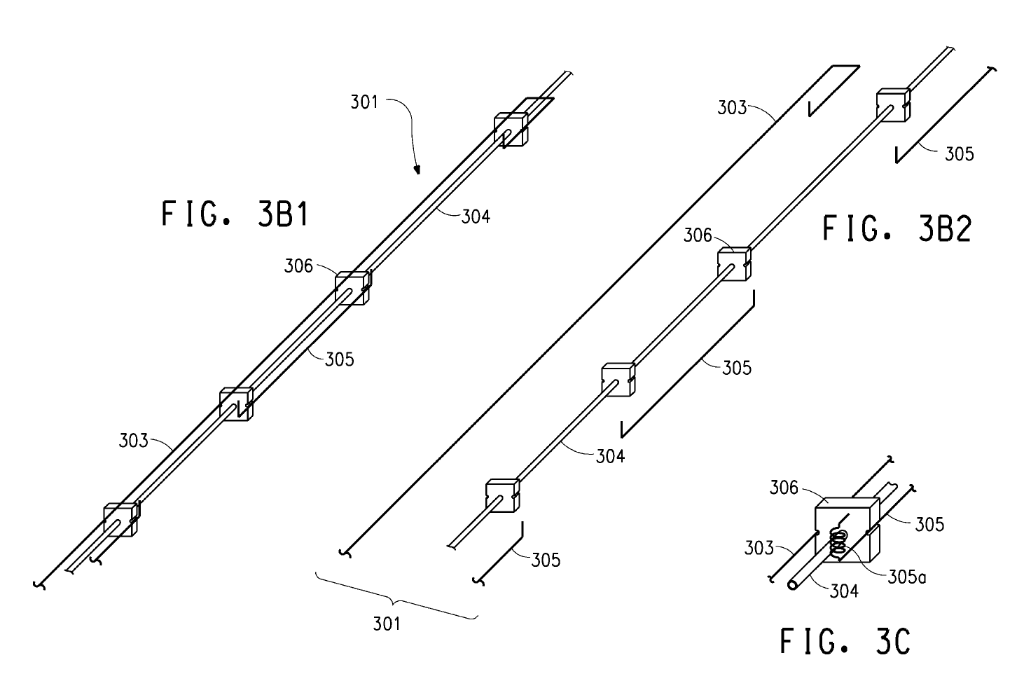

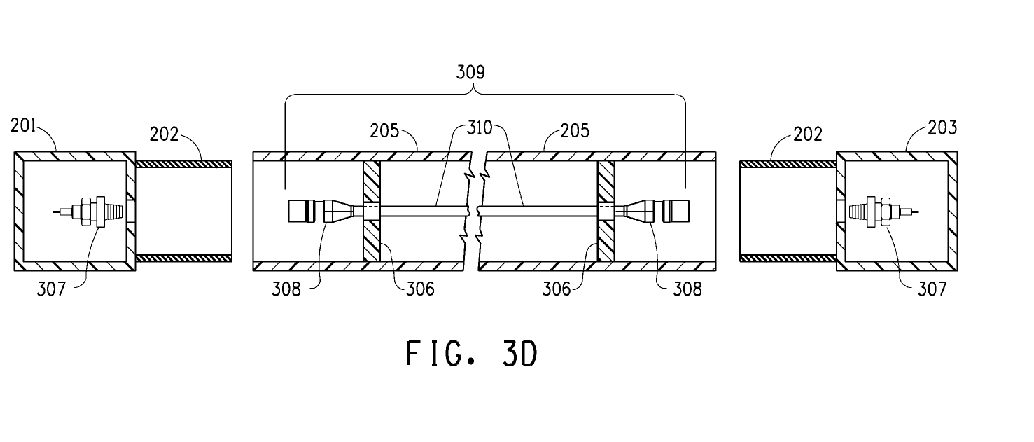

In one embodiment, the photovoltaic module is of a design currently in widespread commercial use, characterized by output conductors that are connected to a junction box mounted on the back of the photovoltaic module with high voltage output wires having weather-tight connectors at the end, as illustrated in FIG. 3D (308 and 307). The output high voltage wires are connected into the framework wiring.

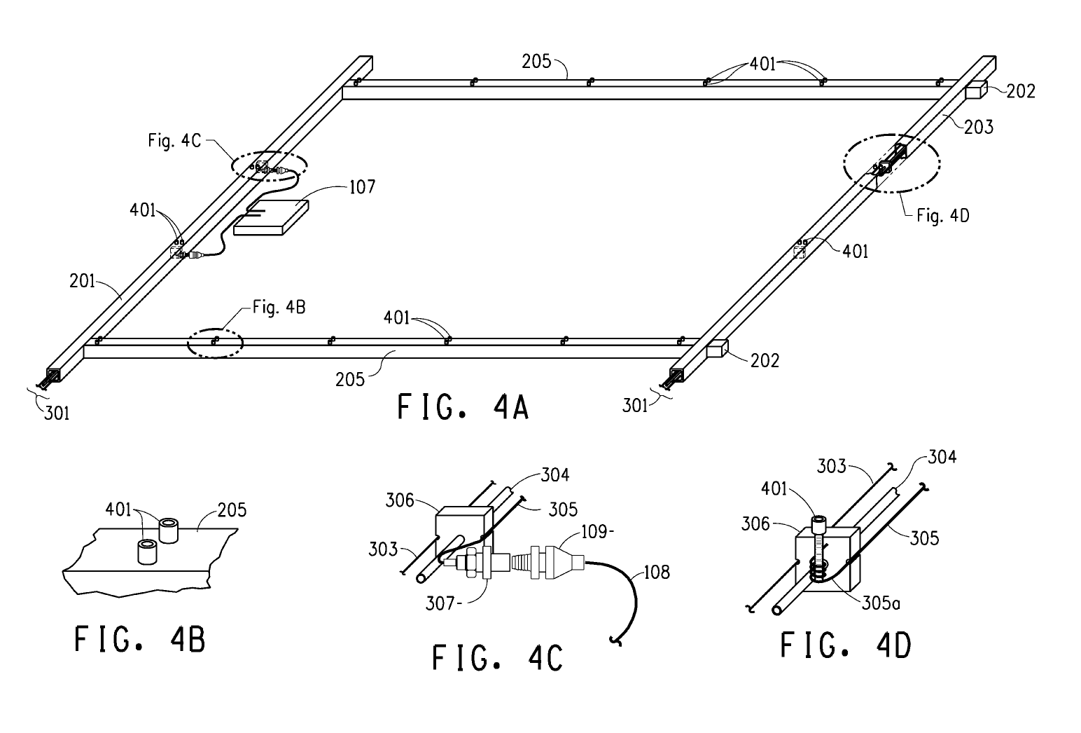

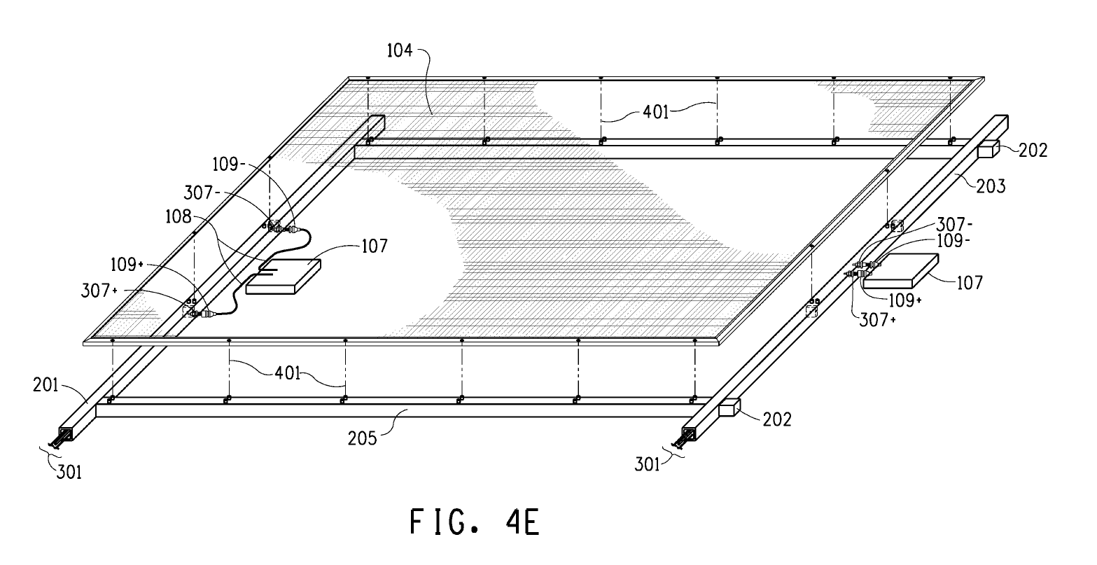

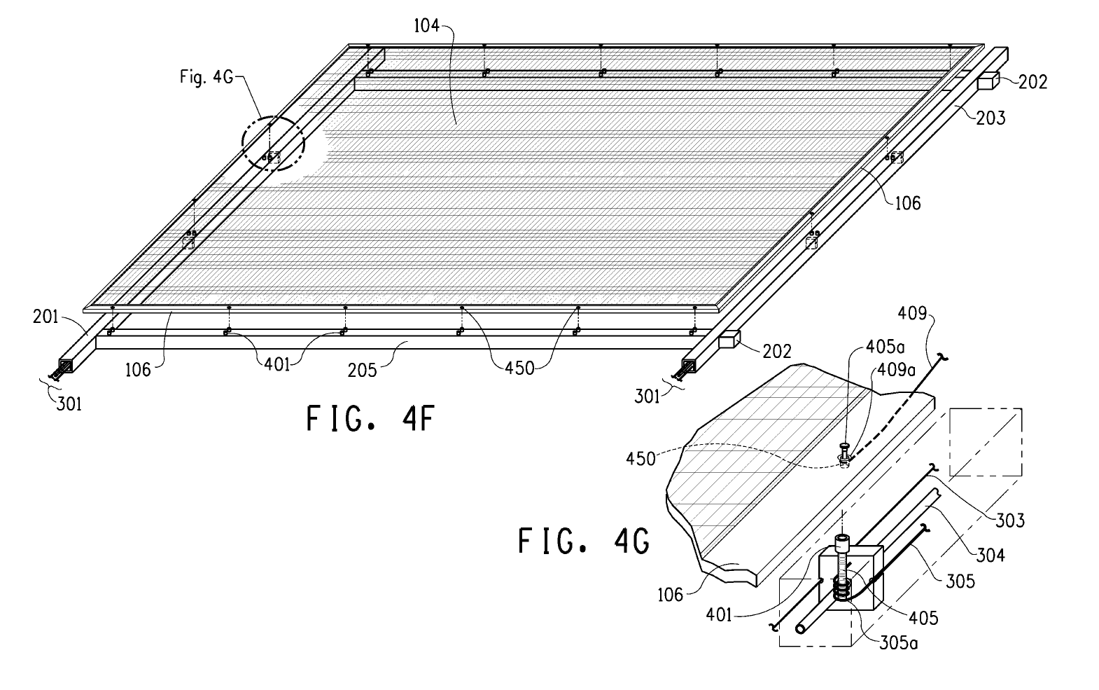

In another embodiment the output high voltage wires such as are present in current commercial offerings are replaced by high voltage connectors mounted right on the junction box, and inserted directly into complementary connectors mounted on the framework element, as illustrated in FIG. 4E right side.

In another embodiment, the photovoltaic module has no external wires. Instead the output wires are run within the module frame to connectors that are coincident with through-holes in the frame that match up to mounting posts on the framework element, thereby achieving both mechanical securing and electrical connection at the same time, as shown in FIGS. 4F and 4G.

In most applications, the photovoltaic array requires some sort of supporting surface on which the framework is constructed. Suitable supporting surfaces include a roof-top, a concrete pad, and the ground. Using known methods currently employed in the art, the framework can be mounted on a moveable sub-structure that enables the array to “follow the sun” across the sky.

In one embodiment, all the rails and stiles are electrically non-conductive hollow members.

In one embodiment, the rails and stiles are fabricated from plastic.

In one embodiment, the plastic is glass-reinforced polyethylene terephthalate.

In one embodiment, the longitudinally extended electrically conductive member is a metallic wire.

In one embodiment, the longitudinally extended electrically conductive member is a metallic buss bar.

In one embodiment, the electrical connections between the photovoltaic modules comprise output wires from the photovoltaic module connected to an electrical junction box, and high voltage output cables from the junction box connected to weather-resistant connectors bulkhead-mounted on one or more the hollow members, with electrical connections between photovoltaic modules effected by electrical conductors internal to at least a portion of the hollow members.

In one embodiment, each rail and stile is fabricated from plastic, each photovoltaic module further comprises a frame segment member enclosing at least a portion of the periphery, the frame segment member housing electrical power output connections; and, wherein all of the electrical conductors and connections that interconnect the photovoltaic modules one to another are internal to at least a portion of the hollow members and the frame segment members.

In one embodiment, the output of the photovoltaic array is connected directly to an electrical load. In an alternative embodiment, the output is processed or conditioned in a step that precedes connection to an external load. In one embodiment, the direct current (DC) output of the photoarray will be directed to a power inverter that converts the DC output to AC, and then to a transformer either for conditioning for long distance high voltage power transmission, or for low voltage local power use.

In one embodiment, the output of the photovoltaic array is delivered by hardwiring to an external electric component such as a power inverter, to convert the high voltage DC generated by the solar cells to the applicable utility grid voltage, frequency and cycles (120 vAC-60 hz-1 phase or 480 vAC-60 hz-3 phase in the US). In an alternative embodiment, the array is provided with a high voltage output disconnect that connects to an external cable. In a further embodiment, the output of the photovoltaic array is used to charge electrical storage devices, such as lead acid batteries, to store electrical power.

In one embodiment, the array is positioned to receive the maximum amount of sunlight. At temperate latitudes, the array is maintained at an angle in the range of 15 to 40° with respect to the horizontal. In a further embodiment the angle is adjusted to maintain maximum exposure to sunlight over the course of the year as the angle of the sun in the sky changes with the seasons.

In one embodiment of the invention, all electrical connections and wiring for the entire array are buried in the structure either within the frame segment of the photovoltaic module or the hollow member of the frame element. In an alternative embodiment, all electrical connections and wiring for the entire array are buried in the structure with the exception of weather-tight high voltage connections between the photovoltaic module and the framework element with which it is associated. In both embodiments, electrical grounding connections are unnecessary.

In the embodiment wherein all electrical connections and wiring for the entire array are buried in the structure either within a frame segment member of the photovoltaic module or the hollow member of the frame element, electrical connections are made as the array is mechanically assembled. In the case where junction boxes and weather-tight high voltage cables are employed, some wiring in-the-field continues to be necessary.

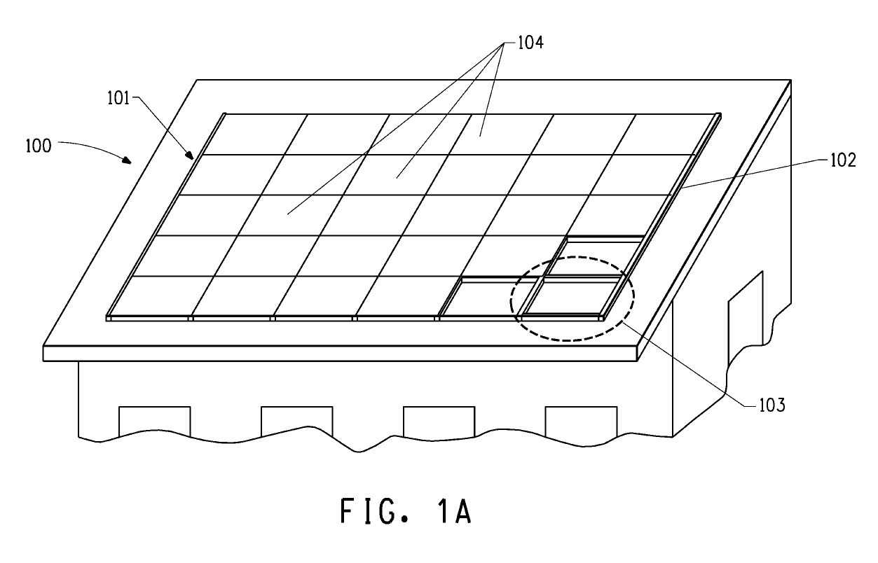

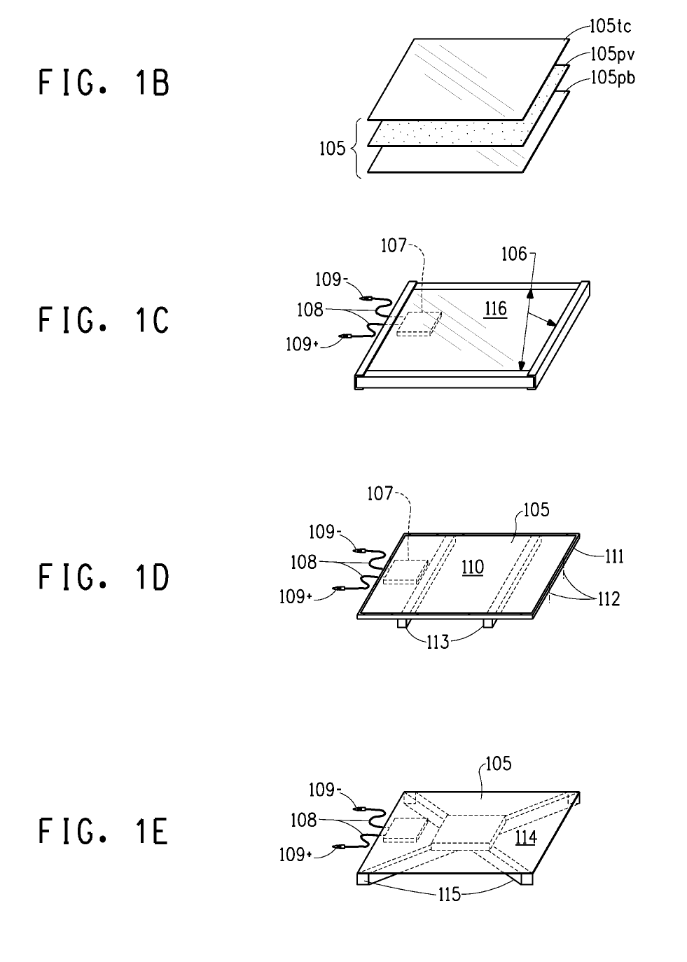

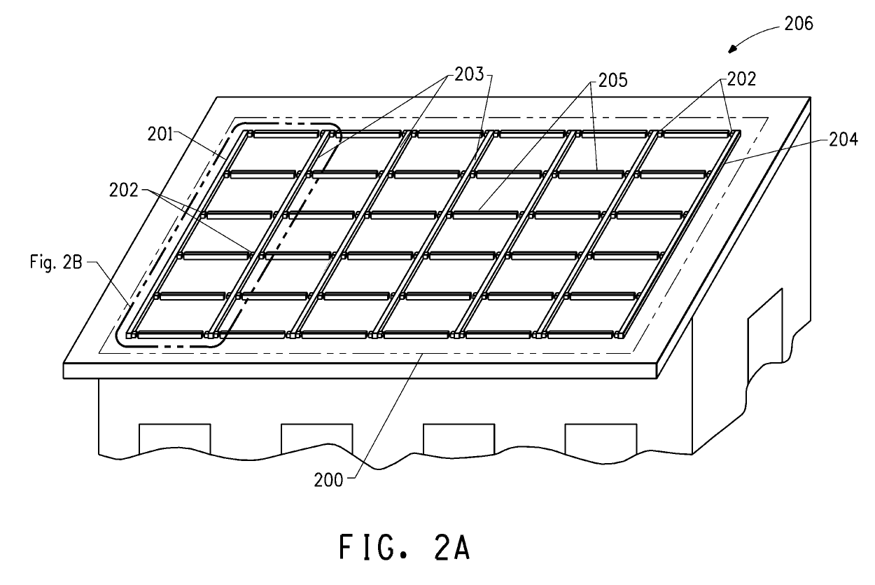

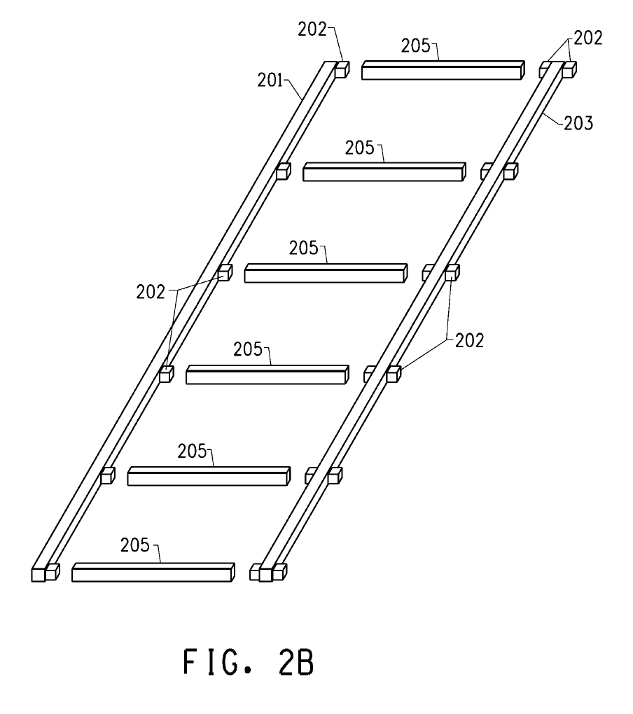

These and other embodiments are depicted in FIGS. 1-5. Throughout the following detailed description similar reference numerals refer to similar elements in all figures of the drawings. It should be understood that various details of the structure and operation of the present invention as shown in various Figures have been stylized in form, with some portions enlarged or exaggerated, all for convenience of illustration and ease of understanding.

FIGS. 1-5 show schematically several closely related embodiments of the device and the method for assembling a photovoltaic array. In the embodiments, the photovoltaic array is installed on a residential, slanted rooftop, common in many parts of the United States. The figures represent only a few of many framework/photovoltaic module geometries possible by this invention.

Numerous other embodiments are envisioned to fall within the invention. These include but are not limited to installations on flat roofs and on the ground. Additional embodiments include but are not limited to those wherein each framework element is individually constructed, and then snapped together in the field to form the array.

One embodiment that can be constructed from those depicted in the figures is an embodiment in which all electrical conductors and connections are fully contained within the framework.

FIG. 1A illustrates one embodiment of a photovoltaic array 101 installed on residential rooftop 100. The photovoltaic array, 101, comprises a framework, 102, each framework element, 103, mechanically and, in some embodiments, electrically connected to another framework element with internal electrical Interconnects. Each framework element, 103, holds a photovoltaic module 104.

FIG. 1B shows the basic sandwich structure, 105, that depicts a general photovoltaic module wherein a photocell array 105pv is located between a clear, protective top layer 105tc, and the protective bottom layer 105pb. Also, shown FIG. 1C through 1E are various types of photovoltaic modules, 116, 110, and 114. Each type of photovoltaic module comprises one or more structural members such as a frame 106 shown in FIG. 1C, in other embodiments support beams in FIG. 1D shown as 113, and in FIG. 1E shown as 115. In one embodiment the structural members of the photovoltaic module are plastic such as a fiber reinforced plastic. Structural members of the photovoltaic module include but are not limited to framing, backing, beams, or other such elements as are required to hold the multi-layer photovoltaic module together, and to resist flexure. In one embodiment the photovoltaic module 116 has a peripheral supporting structural frame 106 that achieves adequate rigidity through a thick, rigid, extrusion surrounding the photovoltaic module. Alternatively, the same degree of structural support can be achieved with a light-weight supporting frame and structural stiffeners 113 bonded to the backside of the photovoltaic module, 110. Alternatively, module 114 has an integrated backside supporting structure 115 In all cases, the brittle, easily damaged photovoltaic cells should be adequately supported and protected to prevent micro-cracking during violent weather if the output of the photovoltaic module is to remain intact for its desired lifetime.

FIGS. 2A and 2B (FIG. 2B is a break-out illustration of FIG. 2A as designated in FIG. 2A) illustrate an embodiment of the method for directly assembling an array of framework elements 103 into the photovoltaic array 101. A first end member, 201, made from 5 cm×5 cm (2×2) cross-section, hollow, fiber-reinforced plastic (FRP) tubing, forms one side of a framework, and a second end member, 204, forms the opposite side of the framework 200. The first end member 201 interconnects with a plurality of rectangular cross section hollow FRP tubing cross-members, 205. Each cross-member 205 is further connected at the opposite end with an intermediate member, 203, of rectangular cross-section hollow FRP tubing provided with plastic interconnects, 202. Unlike the end-members above the intermediate members, 203, are provided with plastic interconnects facing in opposite directions so that the intermediate members 203 can interconnect to cross pieces 205 on both sides of the intermediate member.

FIGS. 2C through 2E illustrate embodiments comprising a matrix of mounting shoes, 207, which attach to the roof, 100, at premeasured locations 209-214, in order to secure the framework members 201, 203, 204 and 205, via mounting feet, 208, affixed beneath some or all of the plastic interconnects, 202. In an embodiment the feet can be plastic. In an embodiment shown in FIG. 2E, the mounting feet, 208, are U shaped pieces, with an open channel 230 in the bottom, which engages the roof-mounted, mating tongue 220 on each corresponding mounting shoe, 207.

Referring to FIG. 3A, each member 201, 203 or 204 (not shown), can contain an internal electrical interconnect wiring harness, 301. In an embodiment shows a fully enclosed hollow interior 327 which accommodates the wiring. This wiring harness replaces the need for field wiring to interconnect the photovoltaic modules into an electrical array. Because the present invention has no exposed metal parts, there is no need for grounding at any point in the array. For purposes of clarity, the wiring harness 301 is broken out separately in FIG. 3B1 and FIG. 3B2, and shown as parts 303, 304, 305, and 306. The components of the wiring harness shown in the figures can be combined if desired into the wiring harness at a remote location such as a factory, away from the in-the-field installation site of the photovoltaic array. As shown in the figures, the wiring harness depicted comprises a return electrical conductor wire 303, a circular perforated reinforcing tube, 304, jumper wires 305 between adjacent framework elements, all of which are snapped onto non-conductive spacers, 306. In one embodiment, the jumper wires are terminated with high voltage connectors such as are currently employed in the art of photovoltaic arrays. In an alternative embodiment, the jumper wires are formed into coils 305a, see FIG. 3C, that are incorporated into an integrated electro-mechanical connection, as discussed below.

In one embodiment, the internal wiring harnesses employed herein can be formed as follows, although the invention is not limited to any particular method for forming the structural members: The spacers 306, as shown in FIG. 3B2, are slid onto a 15-20 foot length of a preferably circular cross-section, preferably perforated, non-conductive rigid tube 304, preferably plastic, to predetermined points along the tubing, to be prepositioned where the electrical connections are to be made to the photovoltaic modules The spacers are then permanently affixed by any suitable means including but not limited to thermal, solvent, or adhesive bonding. Next, the electrically conductive interconnect wires, 303 and 305 are formed to shape dictated by the specific wiring scheme for each specific application. Shaping may be, but need not be, effected by bending over tooling on a bench before snapping them into place on the prepositioned spacers 306.

As shown in FIG. 3A the assembled wiring harness is then inserted into the appropriate end or intermediate member, 201,203, and 204. In one embodiment, the interior of the end and intermediate members after insertion of the wiring harness is sealed with foam, or sealed otherwise to retard the ingress of moisture, oxygen, insects, and debris.

This internal wiring harness eliminates the need for interconnect wiring between photovoltaic modules in the field, if photovoltaic modules with an internal connector design are installed. One embodiment is shown in FIG. 3D.

Referring to FIG. 3D, in some embodiments, the framework cross members 205 contain an internal, electrical interconnect wiring harness 309. This wiring harness replaces the need for some of the field wiring required in other embodiments.

In the embodiment depicted in FIG. 3D, the wiring harness (309) is assembled from one or two electrical jumper wires 310 disposed to connect framework members, 201 and 203, having weather-tight high voltage connectors, 307 (bulkhead) or 308 (plug), all of which are fastened onto non-conductive spacers/holders, 306. Corresponding weather-tight connectors 307 (bulkhead) are installed in each framework interconnect member 202 and electrically connected to the internal wiring harness 301 depicted in FIGS. 3B1 and 3B2. The corresponding plugs in the ends of the framework cross members 205 make a continuous electrical connection with the wiring harness in the members 201, 203, or 204 upon assembly on the roof.

The internal wiring harness in cross member 205 eliminates the need for some of the interconnect wiring between photovoltaic modules during installation on a rooftop. Since the wiring is present in the cross members 205, all that is necessary during installation is to connect the framework elements mechanically and the wiring is concomitantly connected.

In the embodiment shown in FIG. 3A-3D, the plastic interconnect, 202, is in the form of a hollow rectangular shaped tube that is sized to fit into the hollow rectangular aperture of the cross-member. In the practice of the present invention, there is no particular form required for the plastic interconnect. It may, for example, be conical in shape, it may be a truncated square pyramid in shape, prismatic or any shape that will permit the ready interconnection of the end or intermediate members with the cross-members.

The plastic interconnects, 202 can for example be manufactured from appropriately sized tubing in the form of a hollow rectangular prism, cut to length and bonded to the end or intermediate members. Alternatively, the plastic interconnects can be injection molded. Any method of bonding known in the art is satisfactory including mechanical fastening, gluing; thermal bonding; dielectrical bonding; or ultrasonical bonding. The end and intermediate members can also be manufactured with integral interconnects by injection molding or compression molding.

One alternative for achieving firm, positive connection that is also reversible is to employ spring fingers 250 (shown in FIG. 3A) that are molded to or otherwise attached to the exterior surface of the tubing, that are pushed inward when cross member 205 is slid over the open face of interconnect 202 to a pre-determined position at which point the compressed fingers spring out into corresponding holes 251 in cross member 205 to lock the two framework members together. In another embodiment the holes do not penetrate the surface of the cross member. If it is desired to disassemble the framework, the spring fingers 251 can be depressed so that corresponding cross member 205 can be slid off the corresponding plastic interconnect 202. This eliminates all of the drilling and mechanical fastening required in conventional metallic frames, greatly reducing the assembly and installation time on the roof.

FIG. 4A illustrates an embodiment of a single framework element set up to hold one photovoltaic module. Shown in FIG. 4A are two alternative electrical connections, magnified in sections 4C and 4D, and the framework details of the electro-mechanical interconnection between the photovoltaic module and framing elements. Also shown are internally threaded electrically conductive standoffs FIG. 4B, 401 which are bonded to the plastic structural member 205 making up the framework element to affix the intended photovoltaic module atop the framework element. Details of the internally threaded standoffs 401 which hold the photovoltaic module are shown in magnified section of FIG. 4B. The standoffs can be attached to the framework element by installing them into mounting holes drilled into the plastic structural member by heating them with a heated threaded tip, bonding them with adhesive, solvent bonding, or ultrasonically bonding.

The magnified section illustrated in FIG. 4C shows high voltage cables 108 leading from the junction box 107 (shown in FIG. 4A) found on the back of a photovoltaic module (module not shown in FIG. 4C) are plugged into the bulkhead connectors 307 to complete the electrical circuit with the wiring harness, 301 (shown in FIG. 4A), via bulkhead connectors mounted on the member 201 of the framework element. In an embodiment, high-voltage bulkhead connectors are hardwired to the end of wiring elements 305 in the wiring harness, at a remote location, before being transported to the installation site and fastened to the corresponding framework elements 201, 203 or 204 (not shown), followed by placing of the photovoltaic module onto the framework element and securing.

Magnified sections found in FIGS. 4D and 4G illustrate embodiments wherein a coil 305a is wound on the end of a jumper wire 305 or return electrical conductor wire 303 that has the internal diameter of the internally threaded electrically conductive standoffs with insulating caps 401. By positioning the coil 305a beneath the appropriate conductive standoff 401, and inserting an appropriate-length conductive set screw 405 through 401 and into the coil the mechanical standoff doubles as an electrical connection to the photovoltaic module 104 (see FIG. 4F) from the internal wiring harness 301 when the photovoltaic module has an internally wired frame segment member as described above.

FIGS. 4E and 4F each illustrates a single framework element holding one photovoltaic module, 104, via the electro-mechanical standoffs, 401.

FIG. 4E depicts an embodiment in which the photovoltaic module has a junction box 107, interconnect wiring 108 and weather-tight connectors 109. The framework element has mating weather-tight bulkhead fittings 307. In this embodiment, prior to affixing the photovoltaic module to the framework element, the plug connectors 109 are connected to the corresponding bulkhead connectors 308. Following the electrical connection, the panel is positioned on the framework element and connected thereto using the pre-positioned mechanical standoffs 401, and attachment screws.

FIG. 4E also depicts, on the right, the case where the photovoltaic module junction box 107 is mounted close enough to the framework element 203 that only weathertight connectors 109 are needed to connect the junction box 107 to the mating weathertight bulkhead fittings 307, eliminating the cost of the interconnect wiring 108.

FIG. 4G illustrates details of an embodiment in which connectorless connections are made to the wiring harness 301. This connectorless electrical connection invention eliminates the photovoltaic module interconnect wiring 108, having the water-tight connectors 307 and 109, and the junction box 107, all shown in FIG. 4E. These are expensive items which are subject to high failure rates when directly exposed to severe outdoor environments for long periods of time.

In the embodiment depicted in FIGS. 4F and 4G, all conductors and connectors are fully enclosed within the structural members of the photovoltaic array. The junction box is eliminated. In FIG. 4F, a photovoltaic module, 104, is installed onto a frame element defined by structural members 201, 203, and 205, formed by snapping the ends of cross-members 205 onto the appendages 202 disposed on members 201 and 203. The photovoltaic module is provided with a peripheral frame, 106, which houses the wiring, 409, including the isolation diodes (not shown) commonly employed in the art, and connectors, 409a, associated with the module. In the case depicted in FIG. 4G, the connector is just a coil formed at the end of wire 409a. Referring to FIG. 4F, the frame is provided with a series of mounting holes along its surface, 450, which are located to align with the mounting standoffs 401 disposed on the upper surface of the framework element. The mounting standoffs are insulating caps disposed upon a threaded metal element, 405, disposed to receive the mounting screws, 405a. Referring to FIG. 4G, electrical connection is effected by inserting an electrically conductive mounting screw 405a through mounting hole 450 in the frame 106 of the photovoltaic module 104 where the metallic screw 405a comes into electrical contact with connection 409a within the frame, and screws into the threaded metal element 405 which in turn is in electrical contact with connector 305a, thereby forming an electrical connection between 409a and 305a. This method of electrical termination replaces the junction box 107, interconnect wiring 108 and connectors 109, at a significant cost savings, as well as long term reliability.

In the practice of the invention, the framework elements are both electrically and mechanically connected to form an integrated photovoltaic array. All the array wiring and interconnections can be performed at a remote location prior to installation on site. In the embodiment depicted in FIG. 4E, there is a need for making cable connections from the photovoltaic panel to the framework members. In the embodiment depicted in FIG. 4F-4G, there are no cable connections to be made, and the electrical and mechanical connections are made simultaneously, without the necessity of in the field wiring. Because there is no exposed wiring, and no chance of short circuits to exposed metal parts since there aren't any, there is no need for the extensive grounding of the framework such as is commonly done.

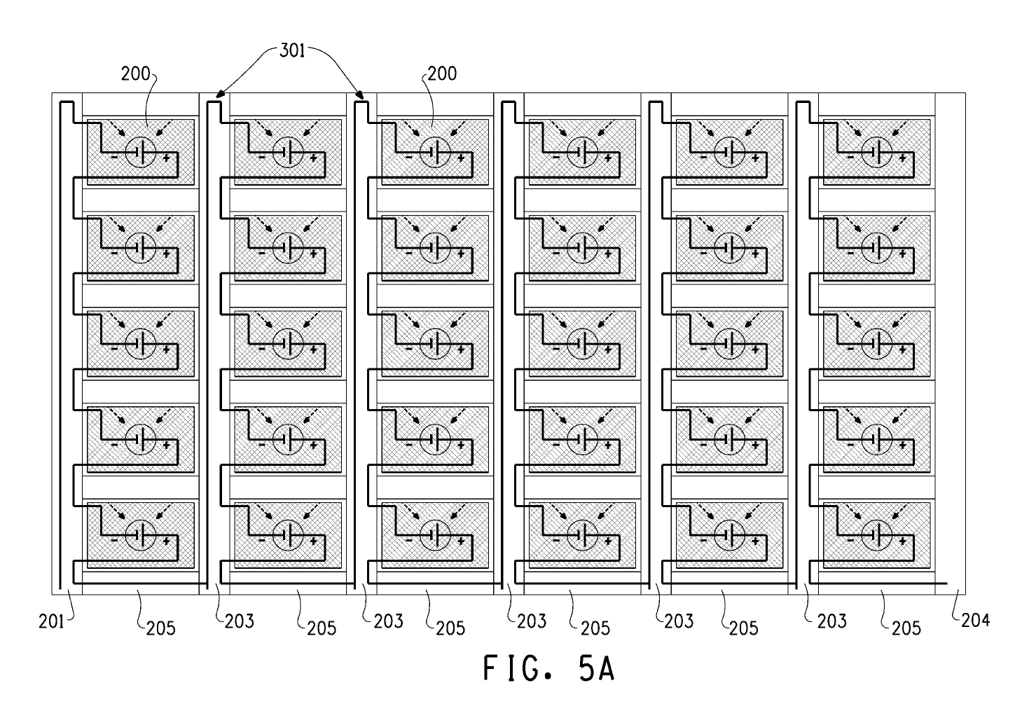

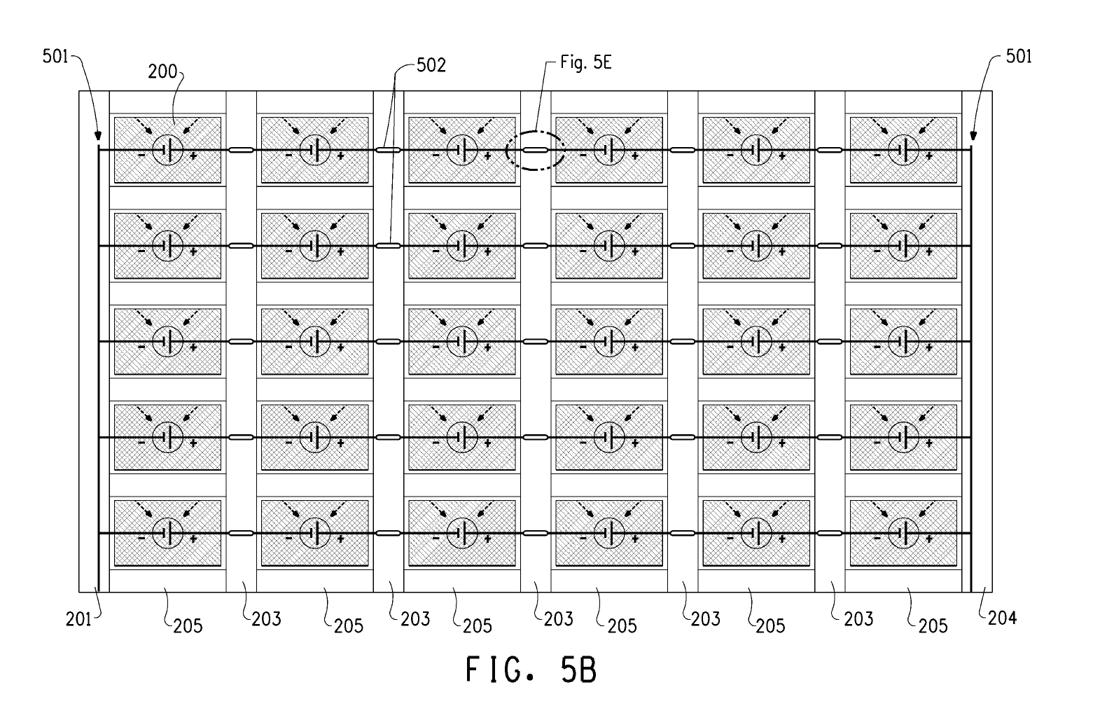

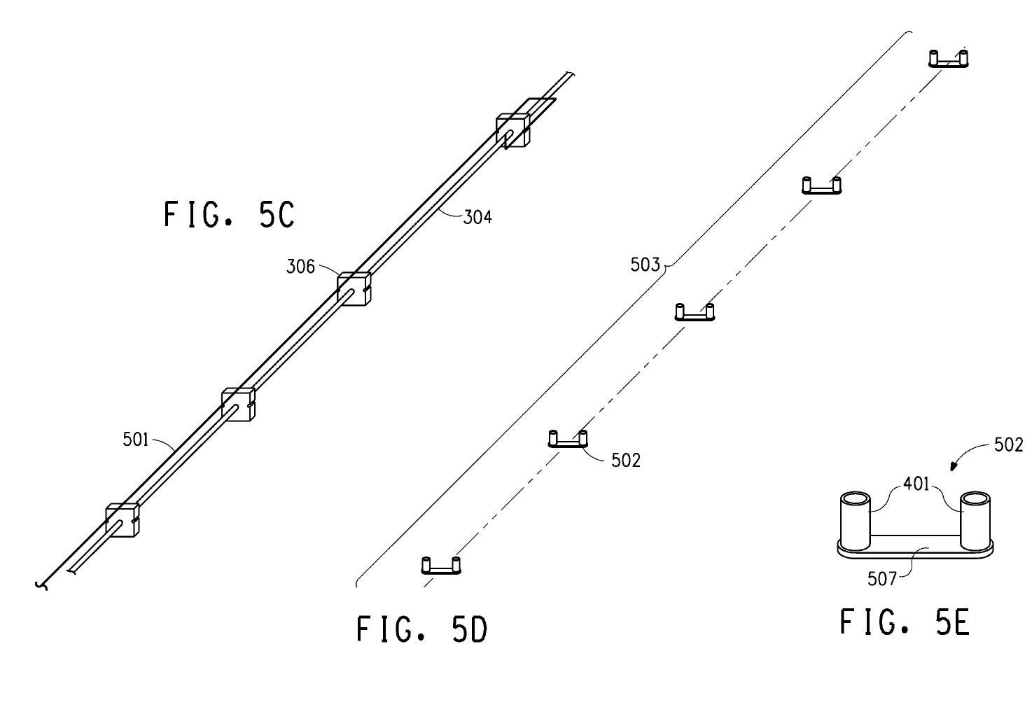

Numerous wiring configurations can be employed in forming the photovoltaic array. FIG. 5A illustrates the photovoltaic modules 200 interconnected in series, with wiring harnesses in framework members 201 and 203. In this wiring scheme, no wiring harness is required in framework element 204. Interconnect wiring is located in the lower cross members 205.

In an alternative embodiment, FIG. 5B illustrates the photovoltaic modules 200 interconnected in series left to right, and in parallel top to bottom. Wiring harnesses 501 are found in framework members 201 and 204, while framework members 203 have short conductive links 502 (see FIG. 5E) between the electro-mechanical fasteners 401 immediately adjacent to each other. These linked standoffs, 502 are inserted inside the vertical framework elements 203 at the factory instead of inserting individual standoffs 401, thereby eliminating altogether the wiring harness 301 or 501 from framework elements 203 for this embodiment. As shown in FIG. 5D, 503 indicates the regularly spaced standoff pairs that can be inserted as a single column into the framework member. This virtually eliminates all panel interconnect wiring and embodies the simplest embodiment.

FIGS. 5C and 5D show an embodiment of a method for connecting adjacent photovoltaic modules together. In FIG. 5C, a buss 501 replaces the wiring harness 301 depicted in FIG. 3B1. FIG. 5D depicts the “jumper lugs” 502 indicated in FIG. 5B; the jumper lugs are mounted on each of the inboard vertical framework elements, 203, greatly simplifying the internal wiring of the photovoltaic array and associated manufacturing costs.

FIG. 5E illustrates the detail of the “jumper lugs” 502 shown in FIG. 5D, consisting of two threaded standoffs, 401, electrically connected by a conductive link, 507.

### LEGEND FOR DRAWINGS

100—residential rooftop
101—assembled photovoltaic (PV) array
102—assembled framework mounted on roof
103—individual framework elements that together make up the framework (102)
104—generic photovoltaic (PV) modules
105—the basic PV module layered structure including the photocell array, 105pv; sandwiched between the clear, protective top layer, 105tc; and the protective bottom layer, 105pb.
106—peripheral supporting structural frame surrounding layered PV structure 105
107—electrical junction box on back of PV panel connecting wiring inside PV module to high voltage electrical leads 108
108—high voltage electrical leads connecting junction box 107 to weather-tight plugs 109
109—weather-tight plugs connecting high voltage electrical leads 108 to bulkhead connectors mounted on framework element
110—One embodiment of a suitable PV module, structurally supported with a light-weight supporting frame, 111, via mounting holes, 112, and structural stiffeners 113 bonded to the backside of the photovoltaic module 105
111—light weight peripheral supporting frame surrounding basic layered PV structure 105
112—mounting holes in light weight peripheral supporting frame
113—structural stiffeners bonded to backside of PV panel 110
114—alternative PV panel, with integrated backside supporting structure, framing or backing 115 bonded to backside
115—integral backside supporting structure for panel
116—embodiment of PV panel with peripheral supporting frame
200—framework
201—framework end member, forming one side of a framework
202—framework mechanical interconnect member bonded to 201, 203, 204
203—framework intermediate member
204—framework end member, forming opposite side of framework
205—framework cross-member
207—mounting shoes, fastened to roof to support framework
208—mounting feet, fastened to framework elements, which engage the roof-mounted, mating tongue on each corresponding mounting shoe, 207
209—location of where left-most framework member 201 will be fastened to roof
210—location where right-most framework member 204 will be fastened to roof
211—location where upper-most foot of framework members 201, 203 and 204, will be fastened to roof
212—location where lower-most foot of framework members 201, 203 and 204, will be fastened to roof
213—location where feet of framework members 203 will be fastened to roof
214—location where rows of framework elements 201, 203 and 204 will be fastened to roof
Point 209,211—upper-left most mounting foot location for framework array
Point 210,211—upper-right most mounting foot location for framework array
Point 209,212—lower-left most mounting foot location for framework array
Point 210,212—lower-right most mounting foot location for framework array
250—spring finger
251—spring finger hole
301—framework element internal electrical interconnect wiring harness, both inside framework elements 201, 202 and 203
303—a return electrical conductor wire
304—a circular perforated reinforcing tube
305—jumper wires between adjacent framework elements
305a—coil of internal electrical wiring forming a connector.
306—non-conductive spacers/wire holders
307—high voltage bulkhead electrical connectors which mate with 308
308—high voltage plug-type electrical connectors which mate with 307
309—internal, electrical interconnect wiring harness in framework cross-pieces 205, which connects wiring harness in framework elements 201, 203 or 204 and consists of components 306, 307, 308, and/or 310
310—jumper wire in wiring harness inside framework crosspiece 205 to connect two adjacent photovoltaic modules
327—hollow enclosed interior
401—insulated standoffs capping mechanical fasteners 405b located in framework element which, with mating fastener, 405a, passing through mounting hole 450 hold module to framework element
405a—conductive screw which connects the module to the framework element via conductive holes 450, insulated standoffs 401, and threaded element 405. In the case of electrical connections 409a and 305a, the screw 405a also effects the electrical connection.
405—threaded conductive element disposed to receive screw 405a
409—electrical lead from the photovoltaic module 105 routed through the surrounding plastic frame 106, to 2 of the mounting holes 450
409a—coil formed at end of conductor 409a to served as electrical connector.
450—mounting hole in module frame
501—electrical buss bar replacing wiring harness 301
502—jumper lugs short conductive link inside framework element 203 to create a series electrical connection of adjacent modules in each row of the photovoltaic array
503—column of short conductive links 502 inside framework member 203
506—magnified view illustrating details of an embodiment in which a short conductive link 507 connects two adjacent mechanical fasteners 401 inside a framework element 203
507—short conductive link

1. A framework comprising a plurality of mechanically and electrically interconnected electrically non-conductive framework elements disposed to supportingly receive and mutually electrically interconnect a plurality of photovoltaic modules, each the framework element comprising:
a pair of generally parallel rails and a pair of generally parallel stiles interconnected therewith, wherein at least one rail and/or at least one stile is an electrically non-conductive hollow member having an interior, the interior defining a fully enclosed guideway;
one or more longitudinally extended electrically conductive member disposed in the at least one enclosed guideway of the non-conductive hollow member;
one or more electrical connector disposed interior to the hollow member;
wherein a combination of the electrically conductive member and the connectors is disposed to electrically interconnect the framework elements to one another forming the framework wherein electrical interconnection of the plurality of photovoltaic modules is accomplished through the non-conductive hollow members of the framework elements.

2. The framework of claim 1 wherein the rails are electrically non-conductive hollow members.

3. The framework of claim 1 wherein the stiles are electrically non-conductive hollow members.

4. The framework of claim 1 wherein the rails and stiles are fabricated from plastic.

5. (canceled)

6. The framework of claim 4 wherein the plastic is glass-reinforced polyethylene terephthalate.

7. (canceled)

8. The framework of claim 1 wherein the longitudinally extended electrically conductive member is a metallic wire.

9. The framework of claim 1 wherein the longitudinally extended electrically conductive member is a metallic buss bar.

10. A photovoltaic array comprising:
a framework comprising a plurality of electrically and mechanically interconnected electrically non-conductive framework elements disposed to supportively receive and mutually electrically interconnect a plurality of photovoltaic modules;
a plurality of photovoltaic modules supportively disposed upon the plurality of framework elements and electrically interconnected therewith, each photovoltaic module having one or more edges that define a periphery;
and,
an electrical connection between the photovoltaic array and an external electrical load; and,
wherein each the framework element comprises
a pair of generally parallel rails and a pair of generally parallel stiles interconnected therewith, wherein at least one rail and/or stile is an electrically non-conductive hollow member having an interior, the interior defining a fully enclosed guideway;
a longitudinally extended electrically conductive member disposed in the at least one enclosed guideway of the non-conductive hollow member;
one or more electrical connectors disposed interior to the at least one hollow member; and,
wherein a combination of the longitudinally extended electrically conductive member and the one or more electrical connectors disposed in the non-conductive hollow elements of the framework elements electrically interconnect the framework elements and the photovoltaic modules to one another.

11. The photovoltaic array of claim 10 wherein the framework element rails and stiles are electrically non-conductive hollow members.

12. The photovoltaic array of claim 10, wherein the framework element the rails and stiles are fabricated from plastic.

13. The photovoltaic array of claim 12 wherein the plastic is glass-reinforced polyethylene terephthalate.

14. The photovoltaic array of claim 10 wherein the longitudinally extended electrically conductive member of the framework element is a metallic wire.

15. The photovoltaic array of claim 10 wherein the longitudinally extended electrically conductive member of the framework element is a metallic buss bar.

16. The photovoltaic array of claim 10 wherein electrical connections between the photovoltaic modules comprise output electrical connection from the photovoltaic module connected to an electrical junction box, and high voltage output cables from the junction box connected to weather-resistant connectors mounted on one or more of the hollow members, with electrical connections between photovoltaic modules effected by electrical conductors internal to at least a portion of the hollow members.

17. (canceled)

18. (canceled)

19. (canceled)

20. (canceled)

21. (canceled)

22. (canceled)

23. (canceled)

24. (canceled)

25. A method comprising illuminating a photovoltaic array with sunlight thereby generating an electrical current from the photovoltaic array, the photovoltaic array comprising
a framework comprising a plurality of interconnected electrically non-conductive framework elements disposed to supportingly receive and mutually interconnect a plurality of photovoltaic modules;
a plurality of photovoltaic modules supportingly disposed upon the plurality of framework elements and interconnected therewith, each photovoltaic module having one or more edges that define a periphery;
and,
an electrical connection between the photovoltaic array and an external electrical load; and,
wherein each the framework element comprises
a pair of generally parallel rails and a pair of generally parallel stiles interconnected therewith, wherein at least one rail and/or stile is an electrically non-conductive hollow member having an interior, the interior defining a fully enclosed guideway;
a longitudinally extended electrically conductive member disposed in the at least one enclosed guideway of the non-conductive hollow member;
one or more electrical connectors disposed interior to the at least one hollow member; and,
wherein a combination of the longitudinally extended electrically conductive member and the at least one connector electrically interconnect the frame elements and the photovoltaic modules to one another, and to an electrical output connection disposed to permit electrical connection of the array to an external electrical load
and,
providing electrical power to the external electrical load.

26. The method of claim 25 wherein in the framework element of the photovoltaic array all the rails and stiles are electrically non-conductive hollow members.

27. (canceled)

28. (canceled)

29. (canceled)

30. (canceled)

31. (canceled)

32. (canceled)
